(19) United States
(12) Patent Application Publication
(10) Pub. No.: US 2023/0080330 A1
(43) Pub. Date: Mar. 16, 2023

(54) METHOD FOR MANUFACTURING SEMICONDUCTOR STRUCTURE, AND SEMICONDUCTOR STRUCTURE

(71) Applicant: CHANGXIN MEMORY TECHNOLOGIES, INC., Hefei City (CN)

(72) Inventor: Meng LI, Hefei (CN)

(21) Appl. No.: 17/717,663

(22) Filed: Apr. 11, 2022

(30) Foreign Application Priority Data
Sep. 10, 2021 (CN) 202111062721.1

(51) Int. Cl. H01L 21/3065; H01J 37/32

(52) U.S. Cl. CPC H01L 21/3065; H01J 37/32082; H01J 2237/334

(57) ABSTRACT

The disclosure relates to a method for manufacturing a semiconductor structure and a semiconductor structure. The method includes: performing etching treatment on a semiconductor structure in a reaction chamber to obtain a first etched structure, and performing preset plasma etching treatment on an upper surface of the first etched structure in the reaction chamber to obtain a second etched structure subjected to removal of etching by-products, the maximum molecular mass of gas for forming preset plasma being less than or equal to the atomic mass of helium, such that the free path of the preset plasma is shorter than the free path of helium atoms under the same etching conditions.

### CROSS-REFERENCE TO RELATED APPLICATIONS

This application is filed based upon and claims priority to Chinese Patent Application No. 202111062721.1, filed on Sep. 10, 2021, the contents of which are hereby incorporated by reference in its entirety.

### BACKGROUND

With the rapid development of the integrated circuit manufacturing process, the market has increasingly higher requirements on the efficiency and yield of the semiconductor manufacturing process. In the semiconductor manufacturing process, etching is an important process for patterning, and the yield of etched structures directly affects the yield of semiconductor products manufactured.

### SUMMARY

On this basis, for the problems in the background, it is necessary to provide a method for manufacturing a semiconductor structure, and a semiconductor structure, so as to prevent the yield of semiconductor products from being affected by granular etching by-products formed and falling onto the upper surface of the semiconductor structure during etching.

The disclosure relates to semiconductor manufacturing, and in particular to a method for manufacturing a semiconductor structure, and a semiconductor structure.

An aspect of the disclosure provides a method for manufacturing a semiconductor structure. The method includes following operations.

Etching treatment is performed on a semiconductor structure in a reaction chamber to obtain a first etched structure.

Preset plasma etching treatment is performed on an upper surface of the first etched structure in the reaction chamber to obtain a second etched structure subjected to removal of etching by-products. The maximum molecular mass of gas for forming the preset plasma is less than or equal to the atomic mass of helium.

The other aspect of the disclosure provides a semiconductor structure, which is manufactured by the method for manufacturing a semiconductor structure according to any one of the embodiments of the disclosure. Preset plasma etching treatment is performed on the upper surface of the first etched structure etched in the reaction chamber to obtain the second etched structure subjected to removal of etching by-products, and the maximum molecular mass in the gas for forming preset plasma is less than or equal to the atomic mass of helium.

### BRIEF DESCRIPTION OF THE DRAWINGS

To better describe and illustrate the embodiments and/or examples of the disclosure, reference may be made to one or more of the drawings. The additional details or examples used to describe the drawings should not be considered as limiting the scope of any of the disclosure, the embodiments and/or examples described presently, and the optimal mode of the disclosure understood presently.

FIG. 1 is a flowchart of a method for manufacturing a semiconductor structure provided in an embodiment of the disclosure.

FIG. 2 is a flowchart of a method for manufacturing a semiconductor structure provided in another embodiment of the disclosure.

FIG. 3 is a flowchart of a method for manufacturing a semiconductor structure provided in a yet another embodiment of the disclosure.

FIG. 4 is a schematic diagram of a cross-sectional structure of a reaction chamber provided in an embodiment of the disclosure.

FIG. 5 is an enlarged view of area A in FIG. 4.

FIG. 6 is a schematic diagram of a cross-sectional structure of a first etched structure provided in an embodiment of the disclosure.

FIG. 7 is a schematic diagram of a cross-sectional structure of a second etched structure provided in an embodiment of the disclosure.

FIG. 8 is a top-view schematic structural diagram of a target etched structure provided in an embodiment of the disclosure.

FIG. 9 is a schematic diagram of a curve representing a corresponding relationship between the ratio of the number of molecules of nitrous oxide in gas for forming the preset plasma to the total number of molecules in the gas and the yield of the manufactured semiconductor structure in an embodiment of the disclosure.

### DESCRIPTION OF REFERENCE NUMERALS

10: first etched structure; 11: second mask layer; 111: first dielectric layer; 112: second dielectric layer; 12: first mask layer; 121: silicon oxynitride layer; 122: carbon layer; 13: first patterned mask layer; 14: granular etching by-product; 15: substrate; 20: second etched structure; 30: preset plasma; 40: target etched structure; 41: capacitor hole; 50: air exhaust port; 200: reaction chamber; 202: inner cavity wall; 203: cleaning by-product layer; 204: protective film.

### DETAILED DESCRIPTION

For ease of understanding of the disclosure, the disclosure is described more fully below with reference to related drawings. Preferred embodiments of the disclosure are shown in the drawings. However, the disclosure can be implemented in many different forms and is not limited to the embodiments described herein. Instead, these embodiments are provided for making the disclosure more thorough and complete.

Unless otherwise specified, all technical and scientific terms used herein have the same meanings as commonly understood by those skilled in the technical field that the disclosure relates to. The terms used in the description of the disclosure are for the purpose of describing specific embodiments only, and are not intended to limit the disclosure. The term “and/or” used herein includes any and all combinations of one or more of associated listed items.

It should be understood that when an element or layer is referred to as being “on”, “adjacent to”, “connected to” or “coupled to” another element or layer, it may be directly on, adjacent to, connected to or coupled to another element or layer, or intervening elements or layers may be present. In contrast, when an element is referred to as being “directly on”, “directly adjacent to”, “directly connected to” or “directly coupled to” another element or layer, there are no intervening elements or layers. It should be understood that though the terms, first, second, third, etc., are used to describe the elements, components, areas, layers and/or sections, those elements, components, areas, layers and/or sections should not be limited by these terms. The terms are merely used to distinguish one element, component, area, layer or section from another element, component, area, layer or section. Thus, a first element, component, area, layer or section, which is discussed below, may be referred to as a second element, component, area, layer or section, without departing from the teaching of the disclosure.

Spatially relative terms, such as “under”, “below”, “lower”, “beneath”, “above”, “upper”, etc., may be used herein for ease of description to describe the relationship between one element or feature and another element or feature as illustrated in the drawings. It should be understood that the spatially relative terms are intended to encompass different orientations of a device in use or operation, in addition to the orientation depicted in the drawings. For example, if the device in the drawings is turned over, an element or feature described as “below” or “beneath” or “under” another element would then be oriented “above” relative to the other element or feature. Therefore, the exemplary terms “below” and “under” can encompass orientations of both above and below. The device may be otherwise oriented (rotated by 90 degrees or at other orientations), and the spatially relative descriptors used herein are interpreted accordingly.

The terms used herein are for the purpose of describing specific embodiments only and are not intended to limit the disclosure. As used herein, the singular forms “a”, “an” and “the/said” are intended to include the plural forms as well, unless the context clearly indicates otherwise. It should be further understood that the terms “consisting of” and/or “include”, when used in this description, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

Embodiments of the disclosure are described herein with reference to cross-sectional diagrams as schematic diagrams of ideal embodiments (and intermediate structures) of the disclosure. Thus, changes from the shown shapes due to, for example, manufacturing techniques and/or tolerances can be expected. Therefore, the embodiments of the disclosure should not be limited to the specific shapes of the area as shown herein, but include shape deviations due to, for example, manufacturing. The areas shown in the drawings are substantially schematic, and their shapes are not intended to illustrate the actual shape of areas of a device and are not intended to limit the scope of the disclosure.

The inventor realized that a large quantity of by-products is produced in the traditional etching process. During plasma etching of wafers, granular by-products are produced and fall onto the surfaces of the wafers, affecting the yield of the semiconductor products.

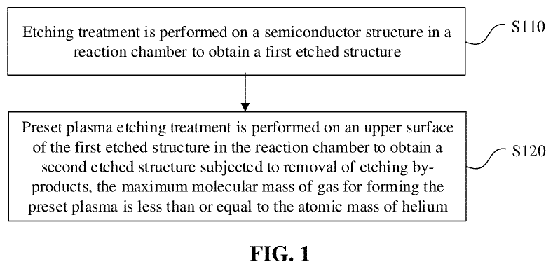

Please refer to FIG. 1 to FIG. 9. It should be noted that the illustrations provided in the embodiments are only to illustrate the basic idea of the disclosure in a schematic way, and although only components related to the disclosure are shown in the drawings and not drawn according to the number, shape, and size of the components in actual implementation, the type, number, and ratio of each component in actual implementation can be arbitrarily changed, and component layout patterns may also be more complex.

With reference to FIG. 1, in one embodiment of the disclosure, provided is a method for manufacturing a semiconductor structure. The method includes the following operations.

S110, etching treatment is performed on a semiconductor structure in a reaction chamber to obtain a first etched structure.

S120, preset plasma etching treatment is performed on an upper surface of the first etched structure in the reaction chamber to obtain a second etched structure subjected to removal of etching by-products. The maximum molecular mass of gas for forming preset plasma is less than or equal to the atomic mass of helium.

Specifically, with continued reference to FIG. 1, preset plasma etching treatment is performed on the upper surface of the first etched structure etched in the reaction chamber to obtain the second etched structure subjected to removal of etching by-products. The maximum molecular mass in the gas for forming preset plasma is less than or equal to the atomic mass of helium. Therefore, the free path of the preset plasma is shorter than the free path of helium atoms under the same etching conditions, and granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, thereby improving the yield of semiconductor products manufactured.

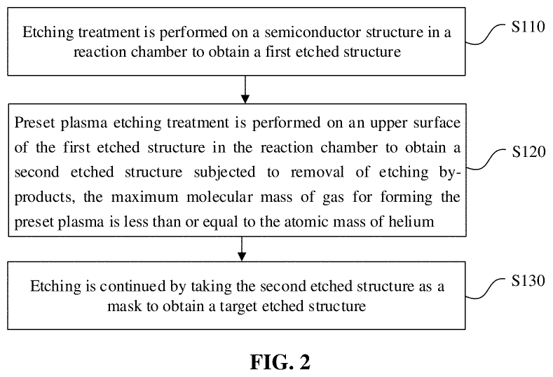

With reference to FIG. 2, in one embodiment of the disclosure, the method for manufacturing a semiconductor structure further includes the following operation.

S130, etching is continued by taking the second etched structure as a mask to obtain a target etched structure.

Specifically, for an integrated circuit semiconductor structure, because an integrated circuit structure is relatively complex, multiple pattern transfers are required in an etching process to manufacture a semiconductor structure that meets functional requirements of an integrated circuit. After obtaining the first etched structure, etching is continued by taking the first etched structure as a mask to obtain a target etched structure that meets the functional requirements of the integrated circuit, or etching may also be continued by taking the target etched structure as a mask to further perform pattern transfer on the target etched structure to obtain a more complex semiconductor structure. Granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, such that the quality and yield of the prepared second etched structure are improved, thereby improving the yield of semiconductor products manufactured.

The foregoing embodiments are intended to illustrate the implementation principle of the disclosure, and do not specifically limit the number of times the etching process is specifically performed.

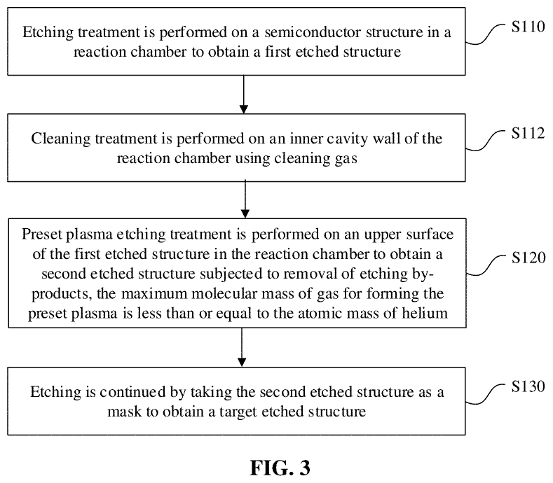

With reference to FIG. 3, in one embodiment of the disclosure, before the operation that preset plasma etching treatment is performed on an upper surface of the first etched structure, the method further includes:

S112, cleaning treatment is performed on an inner cavity wall of the reaction chamber using cleaning gas.

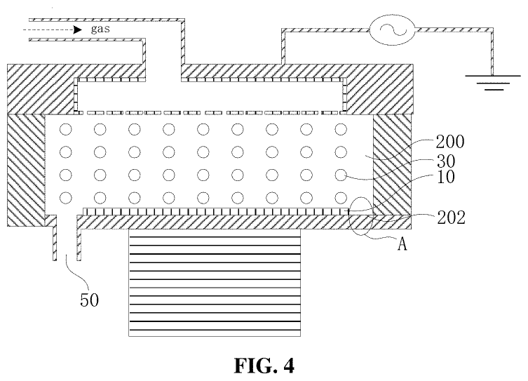

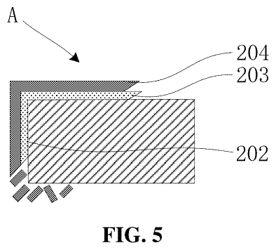

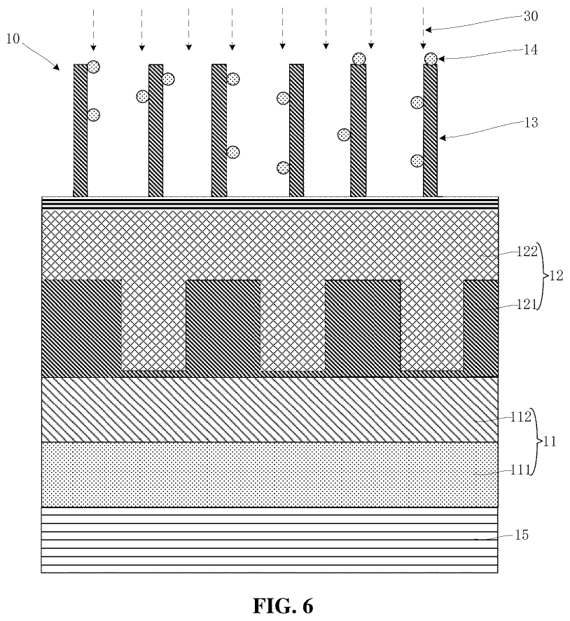

With reference to FIG. 4 to FIG. 7 as examples, after a wafer is etched by preset plasma 30 in a reaction chamber 200, a first etched structure 10 as shown in FIG. 6 is obtained. The first etched structure 10 may include a substrate 15, a second mask layer 11, a first mask layer 12, and a first patterned mask layer 13 stacked in sequence from bottom to top. The second mask layer 11 includes a first dielectric layer 111 and a second dielectric layer 112 stacked in sequence. The second dielectric layer 112 is adjacent to the first mask layer 12. Since cleaning gas will be introduced to clean an inner cavity wall 202 of the reaction chamber 200 during an etching process to prevent the yield of the semiconductor structure manufactured in the subsequent process from being affected by etching by-products on the inner cavity wall 202 of the reaction chamber 200, the cleaning gas chemically reacts with a material of the inner cavity wall 202 to form a cleaning by-product layer 203. For example, after depositing a film, nitrogen trifluoride is used to produce active fluorine ions, so as to produce acidic substances to clean the inner cavity wall of the reaction chamber, and fluoride may chemically react with the surface of the inner cavity wall of the reaction chamber and produce Aluminum Fluoride (AlF). Then, a protective film 204 is grown on the surface of the cleaned inner cavity wall 202 to prevent the plasma from causing damages to the inner cavity wall during the etching process. For example, a material forming the protective film 204 includes silicon dioxide, so as to repair etching damages to the inner cavity wall 202 during the cleaning treatment process, and the silicon dioxide covers and protects the inner cavity wall 202, such that damages to the inner cavity wall 202 by subsequent etching process can be prevented. With continued reference to FIG. 5, due to a complex cavity internal structure, part of the inner cavity wall 202 is not uniformly covered by the protective film 204, such that in the etching process, the plasma bombards the area not uniformly covered by the protective film 204, causing granular etching by-products 14 to be accumulated on the upper surface of the prepared first etched structure 10 as shown in FIG. 6, and affecting the quality and yield of the semiconductor structure obtained by subsequent etching continued by taking the first etched structure 10 as a mask.

As an example, with reference to FIG. 4, the reaction chamber 200 may be configured to be communicated with the outside by means of an air exhaust port 50, and an air pump (not shown) is configured to be connected to the air exhaust port 50, such that the etching by-products, granular solids, etc. can be pumped out by the air pump and discharged out of the reaction chamber 200 from the air exhaust port 50.

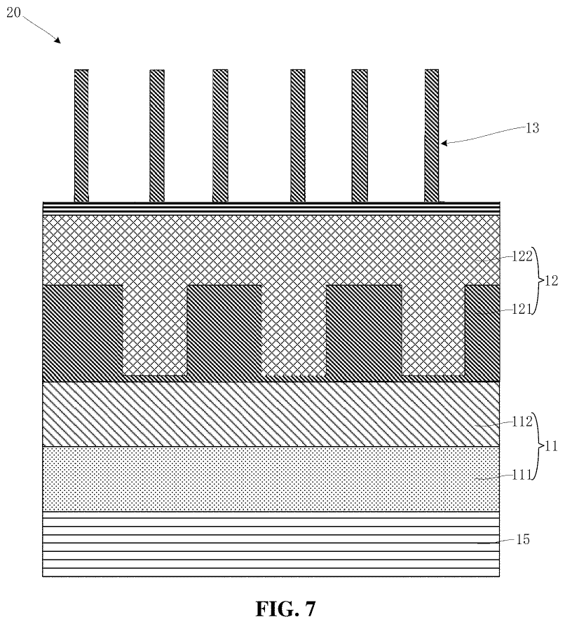

As an example, with reference to FIG. 7, preset plasma etching treatment is performed on the upper surface of the first etched structure etched in the reaction chamber to obtain the second etched structure 20 subjected to removal of etching by-products, and the gas for forming the preset plasma includes at least one of nitrous oxide, nitrogen or oxygen, such that the free path of the preset plasma formed is shorter than the free path of helium atoms under the same etching conditions, and thus granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, thereby improving the yield of semiconductor products manufactured. The gas for forming the preset plasma may further include helium. The atomic mass of helium is smaller than the molecular mass of any one of nitrous oxide, nitrogen or oxygen, and the free path of plasma formed by helium is longer than the free path of plasma formed by any one of nitrous oxide, nitrogen or oxygen under the same etching conditions, such that the etching by-products on the inner cavity wall and the upper surface of the first etched structure can be effectively removed. Because the gas for forming plasma further includes at least one of nitrous oxide, nitrogen or oxygen, compared with performing cleaning treatment on the inner cavity wall by forming plasma using helium only, the granular solids formed by the preset plasma bombarding and etching a surface of an inner cavity wall can be prevented from falling onto the upper surface of the first etched structure in the process of using the preset plasma for etching to remove the etching by-products on the upper surface of the first etched structure, thereby improving the yield of semiconductor products manufactured. As an example, in this embodiment, the etching by-products, granular solids, etc. may be pumped out by means of an air pump (not shown). The air pump is connected to the air exhaust port 50 and configured to remove the etching by-products or granular matter in the reaction chamber 200.

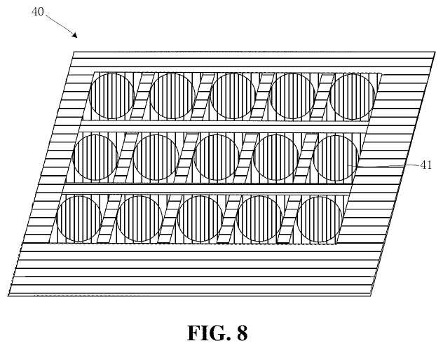

As an example, with reference to FIG. 8, etching is continued by taking the second etched structure as a mask to obtain a target etched structure 40 including several capacitor holes 41. For example, with continued reference to FIG. 7, the second etched structure 20 may include a substrate 15, a second mask layer 11, a first mask layer 12, and a first patterned mask layer 13 stacked in sequence from bottom to top. The first mask layer 12, second mask layer 11, and substrate 15 may be etched by taking the first patterned mask layer 13 as a mask to obtain a target etched structure 40 including several capacitor holes 41. The second mask layer 11 includes a first dielectric layer 111 and a second dielectric layer 112 stacked in sequence, and the second dielectric layer 112 is adjacent to the first mask layer 12. Compared with the target etched structure 40 including several capacitor holes 41 obtained by continuing etching by taking the first etched structure 10 in FIG. 7 as a mask, in this embodiment, granular etching by-products 14 on the upper surface of the first etched structure 10 are removed to prevent the granular etching by-products 14 from affecting the uniformity of pattern transfer of the capacitor holes, such that the size of the capacitor holes 41 in the prepared target etched structure 40 is more uniform, and coupling between the capacitor holes 41 is prevented, thereby effectively improving the quality and yield of the semiconductor structure manufactured.

As an example, with reference to FIG. 7 and FIG. 8, a material for preparing the first dielectric layer 111 may include silicon dioxide. Materials for preparing the second dielectric layer 112 may include carbon. The first mask layer 12 may include a silicon oxynitride layer 121 and a carbon layer 122 stacked in sequence. The carbon layer 122 is adjacent to the first patterned mask layer 13. Materials for preparing the first patterned mask layer 13 may include silicon dioxide.

As an example, the flow rate of the gas for forming the preset plasma is greater than 0 sccm and less than or equal to 6,300 sccm. For example, the flow rate of the gas for forming the preset plasma is greater than 0 sccm and less than or equal to 6,300 sccm, so as to prevent granular solids formed by the preset plasma bombarding and etching a surface of an inner cavity wall from falling onto the upper surface of the first etched structure in a process of using the preset plasma for etching to remove the etching by-products on the upper surface of the first etched structure, thereby improving the yield of semiconductor products manufactured.

As an example, the gas for forming the preset plasma includes nitrous oxide, and the content of nitrous oxide in the gas is 70%-90%. For example, the content of nitrous oxide in the gas for forming the preset plasma may be 70%, 75%, 80%, 85% or 90%, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

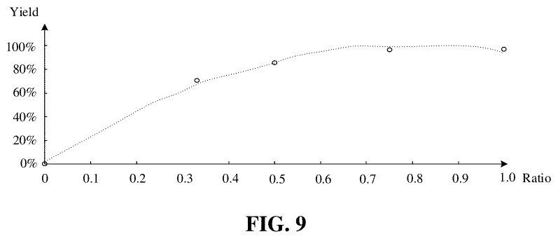

As an example, the gas for forming the preset plasma includes nitrous oxide and helium. In FIG. 9, a horizontal axis represents the ratio of the number of molecules of nitrous oxide in the gas for forming the preset plasma to the total number of molecules of the gas, and a vertical axis represents the yield corresponding to each ratio. It can be seen that if the ratio of the number of molecules of nitrous oxide in the gas for forming the preset plasma to the total number of molecules of the gas is 0.5-1.0. For example, the ratio of the number of molecules of nitrous oxide in the gas for forming the preset plasma to the total number of molecules of the gas is 0.5, 0.6, 0.75, 0.8, 0.9 or 1.0, etc., and the yield of the second etched structure or target etched structure obtained is relatively high, where when the ratio of the number of molecules of nitrous oxide in the gas for forming the preset plasma to the total number of molecules of the gas is 0.75, the corresponding yield is highest. Therefore, the ratio of the number of molecules of nitrous oxide in the gas for forming the preset plasma to the total number of molecules of the gas may be configured to 0.5-1.0, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured. Moreover, the cost of nitrous oxide is lower than the cost of helium. Compared with the traditional etching process in which helium is used to form plasma for etching, replacing part or all of helium with nitrous oxide can reduce etching costs.

As an example, the flow rate of the gas for forming the preset plasma is greater than 0 sccm and less than or equal to 3,000 sccm. For example, the flow rate of helium in the gas for forming the preset plasma may be 500 sccm, 1,000 sccm, 1,500 sccm, 2,000 sccm, 2,500 sccm or 3,000 sccm, etc., so as to effectively remove the etching by-products on the upper surface of the first etched structure, ensure the etching efficiency, and avoid the waste of etching gas, thereby controlling costs of the etching process.

As an example, a preset plasma etching treatment is performed on the upper surface of the first etched structure with a pressure 4-6 torr. For example, a preset plasma etching treatment may be performed on the upper surface of the first etched structure with a pressure of 4 torr, 5 torr or 6 torr, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

As an example, the preset plasma etching treatment is performed on the upper surface of the first etched structure with radio frequency energy of 500-700 W. For example, the preset plasma etching treatment may be performed on the upper surface of the first etched structure with radio frequency energy of 500 W, 600 W or 700 W, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

In one embodiment of the disclosure, provided is a semiconductor structure, which is manufactured by the method for manufacturing a semiconductor structure according to any one of the embodiments of the disclosure. Preset plasma etching treatment is performed on the upper surface of the first etched structure etched in the reaction chamber to obtain the second etched structure subjected to removal of etching by-products, and the maximum molecular mass in the gas for forming preset plasma is less than or equal to the atomic mass of helium. Therefore, the free path of the preset plasma is shorter than the free path of helium atoms under the same etching conditions, and thus granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, thereby improving the yield of semiconductor products manufactured.

In one embodiment of the disclosure, the removed etching by-products/granular solids, etc. may be pumped out of the reaction chamber by means of an air pump.

In the method for manufacturing a semiconductor structure according to the embodiment above, preset plasma etching treatment is performed on the upper surface of the first etched structure etched in the reaction chamber to obtain the second etched structure subjected to removal of etching by-products, and the maximum molecular mass of the gas for forming preset plasma is less than or equal to the atomic mass of helium. Therefore, the free path of the preset plasma is shorter than the free path of helium atoms under the same etching conditions, and thus granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, thereby improving the yield of semiconductor products manufactured.

In one embodiment, the method for manufacturing a semiconductor structure may further include the following operation. Etching is continued by taking the second etched structure as a mask to obtain a target etched structure, so as to improve the quality and yield of the target etched structure manufactured.

In one embodiment, before the operation that preset plasma etching treatment is performed on an upper surface of the first etched structure, the method may further include: cleaning treatment is performed on an inner cavity wall of the reaction chamber using cleaning gas. The yield of the semiconductor structure manufactured in the subsequent process is prevented from being affected by the etching by-products on the inner cavity wall of the reaction chamber.

In one embodiment, the method for manufacturing a semiconductor structure may further include following operation: a protective film is deposited on the surface of the inner cavity wall after cleaning treatment, so as to repair etching damages to the inner cavity wall during a cleaning treatment process.

In one embodiment, the cleaning gas may include nitrogen trifluoride, so that after depositing the film, nitrogen trifluoride is used to produce active fluorine ions, so as to produce acidic substances to clean the inner cavity wall of the reaction chamber.

In one embodiment, a material forming the protective film may include silicon dioxide, so as to repair etching damages to the inner cavity wall during the cleaning treatment process. Moreover, silicon dioxide covers and protects the inner cavity wall, such that damages to the inner cavity wall by subsequent etching process can be prevented.

In one embodiment, the gas for forming the preset plasma may include at least one of nitrous oxide, nitrogen or oxygen, such that the free path of the preset plasma formed is shorter than the free path of helium atoms under the same etching conditions, and thus granular solids formed by the preset plasma bombarding and etching a surface of an inner cavity wall are prevented from falling onto the upper surface of the first etched structure in a process of using the preset plasma for etching to remove the etching by-products on the upper surface of the first etched structure, thereby improving the yield of semiconductor products manufactured.

In one embodiment, the gas for forming the preset plasma may further include helium. The atomic mass of helium is smaller than the molecular mass of any one of nitrous oxide, nitrogen or oxygen. The free path of plasma formed by helium is longer than the free path of plasma formed by any one of nitrous oxide, nitrogen or oxygen under the same etching conditions, such that the etching by-products on the inner cavity wall and the upper surface of the first etched structure can be effectively removed. Because the gas for forming plasma also includes at least one of nitrous oxide, nitrogen or oxygen, compared with performing cleaning treatment on the inner cavity wall by forming plasma using helium only, the granular solids formed by the preset plasma bombarding and etching a surface of an inner cavity wall can be prevented from falling onto the upper surface of the first etched structure in a process of using the preset plasma for etching to remove the etching by-products on the upper surface of the first etched structure, thereby improving the yield of semiconductor products manufactured.

In one embodiment, the flow rate of the gas for forming the preset plasma may be greater than 0 sccm and less than or equal to 6,300 sccm, so as to prevent granular solids formed by the preset plasma bombarding and etching a surface of an inner cavity wall from falling onto the upper surface of the first etched structure in a process of using the preset plasma for etching to remove the etching by-products on the upper surface of the first etched structure, thereby improving the yield of semiconductor products manufactured.

In one embodiment, the gas for forming the preset plasma includes nitrous oxide, and the content of nitrous oxide in the gas is 70%-90%, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

In one embodiment, the flow rate of helium may be greater than 0 sccm and less than or equal to 3,000 sccm, so as to effectively remove the etching by-products on the upper surface of the first etched structure, ensure the etching efficiency, and avoid the waste of etching gas, thereby controlling costs of the etching process.

In one embodiment, the gas for forming the preset plasma may include nitrous oxide and helium, where a ratio of the number of molecules of nitrous oxide to the total number of molecules of the gas is 0.5-1.0, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

In one embodiment, a preset plasma etching treatment may be performed on the upper surface of the first etched structure with a pressure of 4-6 torr, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

In one embodiment, the preset plasma etching treatment may be performed on the upper surface of the first etched structure with radio frequency energy of 500-700 W, so as to effectively remove the etching by-products on the upper surface of the first etched structure and prevent granular solids formed by the preset plasma bombarding and etching a surface of an inner cavity wall from falling onto the upper surface of the first etched structure, thereby improving the yield of semiconductor products manufactured.

Please note that the foregoing embodiments are for illustrative purposes only and are not meant to limit the disclosure.

It should be understood that steps described are not strictly limited to the order in which they are performed, and that the steps may be performed in other orders, unless explicitly stated herein. Moreover, at least some of the described steps may include multiple sub-steps or multiple stages, and these sub-steps or stages are not necessarily performed and completed at the same time, but may be performed at different times. These sub-steps or stages are also not necessarily performed in sequence, but may be performed in turn or alternately with other steps or at least some of the sub-steps or stages of other steps.

The embodiments in the description are all described in a progressive manner, and each embodiment focuses on the differences from other embodiments, and the same and similar parts between the embodiments may be referred to each other.

The technical features of the foregoing embodiments can be combined arbitrarily. In order to simplify the description, all possible combinations of the technical features in the foregoing embodiments are not described. However, as long as the combinations of these technical features are not contradictory, they should all be considered to fall within the scope of the description.

The foregoing embodiments only represent several embodiments of the disclosure, and the descriptions are relatively specific and detailed, but should not be construed as limiting the scope of the claims. It should be pointed out that for those skilled in the art, several improvements and modifications can be made without departing from the concept of the disclosure, and these improvements and modifications all fall within the scope of protection of the disclosure. Therefore, the scope of protection of the patent disclosure shall be subject to the scope of protection of the appended claims.

1. A method for manufacturing a semiconductor structure, comprising:
performing etching treatment on a semiconductor structure in a reaction chamber to obtain a first etched structure; and
performing preset plasma etching treatment on an upper surface of the first etched structure in the reaction chamber to obtain a second etched structure subjected to removal of etching by-products, wherein maximum molecular mass of gas for forming the preset plasma is less than or equal to atomic mass of helium.

2. The method of claim 1, further comprising:
continuing etching by taking the second etched structure as a mask to obtain a target etched structure.

3. The method of claim 2, before the performing preset plasma etching treatment on an upper surface of the first etched structure, further comprising:
performing cleaning treatment on an inner cavity wall of the reaction chamber using cleaning gas.

4. The method of claim 3, further comprising:
depositing a protective film on a surface of the inner cavity wall after the cleaning treatment.

5. The method of claim 4, wherein the cleaning gas comprises nitrogen trifluoride.

6. The method of claim 4, wherein a material forming the protective film comprises silicon dioxide.

7. The method of claim 1, wherein the gas for forming the preset plasma comprises at least one of nitrous oxide, nitrogen or oxygen.

8. The method of claim 7, wherein the gas for forming the preset plasma further comprises helium.

9. The method of claim 7, wherein a flow rate of the gas for forming the preset plasma is greater than 0 sccm and less than or equal to 6,300 sccm.

10. The method of claim 7, wherein the gas for forming the preset plasma comprises nitrous oxide, and content of nitrous oxide in the gas is 70%-90%.

11. The method of claim 8, wherein a flow rate of helium is greater than 0 sccm and less than or equal to 3,000 sccm.

12. The method of claim 8, wherein the gas for forming the preset plasma comprises nitrous oxide and helium, wherein a ratio of number of molecules of nitrous oxide to total number of molecules of the gas is 0.5-1.0.

13. The method of claim 1, wherein the preset plasma etching treatment is performed on the upper surface of the first etched structure with a pressure of 4-6 torr.

14. The method of claim 1, wherein the preset plasma etching treatment is performed on the upper surface of the first etched structure with radio frequency energy of 500-700 W.

15. A semiconductor structure, manufactured by the method for manufacturing a semiconductor structure according to claim 1.
